(19) United States
(12) Patent Application Publication
(10) Pub. No.: US 2006/0172501 A1
(43) Pub. Date: Aug. 3, 2006

(54) Method of manufacturing semiconductor device

(75) Inventors: Tetsuji Ueno, Suwon-si (KR); Dong-suk Shin, Yongin-si (KR); Hwa-sung Rhee, Seongnam-si (KR); Ho Lee, Cheonan-si (KR); Seung-hwan Lee, Suwon-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/346,107

(22) Filed: Feb. 2, 2006

(30) Foreign Application Priority Data
Feb. 3, 2005 (KR) 10-2005-0010095

(51) Int. Cl. H01L 21/336

(52) U.S. Cl. 438/300

(57) ABSTRACT

Provided is a method of manufacturing a high-quality silicon epitaxial growth. (SEG) layer on a highly doped silicon substrate. The method includes providing a semiconductor substrate including dopant areas with a predetermined concentration, implanting group IV ions into the substrate, cleaning the substrate using a chlorine-based gas, and forming a silicon epitaxial growth (SEG) layer on the substrate.

This application claims priority from Korean Patent Application No. 10-2005-0010095 filed on Feb. 3, 2005 in the Korean Intellectual Property Office, the contents of which are incorporated herein by reference in their entirety.

### BACKGROUND OF THE INVENTION

1. Field of the Invention

The present invention relates to a method of manufacturing a semiconductor device, and more particularly, to a method of forming a high-quality silicon epitaxial growth layer on a highly doped silicon substrate.

2. Description of the Related Art

Recently, a silicon selective epitaxial growth (SEG) technology is often used in manufacturing processes of semiconductor devices. For example, the silicon SEG technology is widely used in device separation processes and source and drain areas and metallic plug filling processes.

Advancement in integration level of semiconductor devices has led to a gradual decrease in the size of a unit device. Hence, there exist many difficulties in applying conventional deposition and etch processes without adversely affecting desired characteristics of the device.

In general, the silicon epitaxial growth process includes selectively forming an epitaxial growth layer on the surface of a highly doped silicon substrate. In order to grow the epitaxial growth layer on the surface of the highly doped silicon substrate, contaminants are removed from the substrate by wet cleaning.

FIG. 1 is a graph illustrating the removal rates of contaminants from the interface between a substrate and a silicon epitaxial growth layer after a conventional wet cleaning.

Referring to FIG. 1, contaminants, such as carbon (C), remain on the interface between the substrate and the silicon epitaxial layer even after the wet cleaning. Accordingly, in order to form an epitaxial growth layer selectively on the surface of the highly doped silicon substrate, after the wet cleaning step, it is necessary to perform a pre-cleaning step, e.g., a low pressure H₂ baking step. Such a low pressure H₂ baking step is performed at a high temperature of over 900° C., which is undesirable in view of thermal budget considerations.

In order to solve such a problem, an ultra high vacuum annealing or an H₂ baking is provided for the pre-cleaning. Such a method is performed at a relatively lower temperature than the low pressure H₂ baking step; however, it is difficult to obtain an epitaxial growth layer from a highly doped silicon substrate and the quality of the epitaxial growth layer is low. On the other hand, cleaning using H₂ plasma at a temperature of lower than 700° C. may be used; however, it is still difficult to obtain an epitaxial growth layer from a highly doped silicon substrate. In addition, since the pre-cleaning and the forming of the epitaxial growth layer are performed in one chamber, the substrate may be re-contaminated after the pre-cleaning.

As described above, it is difficult to obtain a high-quality epitaxial growth layer from the highly doped silicon substrate.

### SUMMARY OF THE INVENTION

The present invention provides a method of manufacturing a semiconductor device to obtain a high-quality epitaxial growth layer at a low temperature.

The present invention also provides a method of manufacturing a semiconductor device to obtain a high-quality epitaxial growth layer by preventing re-contamination after a pre-cleaning.

According to an aspect of the present invention, there is provided a method of manufacturing a semiconductor device, comprising providing a semiconductor substrate including dopant areas with a predetermined concentration, implanting group IV ions into the substrate, cleaning the substrate using a chlorine-based gas, and forming a silicon epitaxial growth (SEG) layer on the substrate.

In one embodiment, the cleaning and the forming of the SEG layer are performed in-situ.

The chlorine-based gas can be HCl gas.

Cleaning the substrate can be performed at a temperature lower than 850° C.

In one embodiment, in the implanting of the group IV ions, the group IV ions are implanted to a depth sufficient to change the dopant areas of the semiconductor substrate into amorphous areas. In the implanting of the group IV ions, the concentration of the group IV ions can be in the range of 10¹⁴ to 10¹⁶ atom/cm³.

The group IV ions can be carbon (C), silicon (Si), or germanium (Ge) ions.

In one embodiment, in the providing of the semiconductor substrate, the dopant can be boron (B), phosphorus (P), arsenic (As), or carbon (C).

In one embodiment, the method further comprises annealing the semiconductor substrate before and/or after the cleaning of the substrate. In one embodiment, the cleaning of the substrate is performed at a temperature lower than the temperature of the annealing. In one embodiment, the annealing is performed at a temperature in the range of 650 to 850° C. The annealing can be performed at the same time as the cleaning. The annealing can be performed under an H₂ atmosphere.

According to another aspect of the present invention, there is provided a method of manufacturing a semiconductor device, the method including providing a semiconductor substrate having dopant areas with a predetermined concentration, implanting germanium ions into the substrate and changing the substrate into an amorphous substrate, cleaning the substrate at a temperature lower than 850° C. using HCl gas, and forming an SEG layer on the substrate in-situ.

In one embodiment, in the implanting of the germanium ions, the germanium ions are implanted to a depth sufficient to change the dopant areas of the semiconductor substrate into amorphous areas. In the implanting of the germanium ions, the concentration of the germanium ions can be in the range of 10¹⁴ to 10¹⁶ atom/cm³.

In one embodiment, in the providing of the semiconductor substrate, the dopant can be boron (B).

In one embodiment, the method further comprises annealing the semiconductor substrate before and/or after the cleaning of the substrate. The cleaning of the substrate can be performed at a temperature lower than the temperature of the annealing. The annealing can be performed at a temperature in the range of 650 to 850° C. The annealing can be performed at the same time as the cleaning. In one embodiment, the annealing is performed under an H₂ atmosphere.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIG. 1 is a graph illustrating a removal rate of a contaminant from an interface between a substrate and a silicon epitaxial growth layer after a wet cleaning of the surface of a highly doped silicon substrate.

FIG. 2 is a flowchart of a method of manufacturing a semiconductor device according to a first embodiment of the present invention.

FIGS. 3A through 3D are sectional views of a semiconductor device in manufacturing stages according to the first embodiment of the present invention.

FIGS. 4 through 6 are flowcharts of a method of manufacturing a semiconductor device according to second through fourth embodiments, respectively, of the present invention.

FIG. 7 is a graph illustrating process conditions for cleaning, annealing, and selective epitaxial growth (SEG) layer forming included in the method of manufacturing a semiconductor device according to the second through fourth embodiments of the present invention, wherein (1), (2), and (3) denote the process conditions according to the second through fourth embodiments of the present invention, respectively, and A, C, and SEG denote the annealing, the cleaning, and the SEG forming, respectively.

FIG. 8 is a graph illustrating the removal rate of a contaminant from the interface between a substrate and an SEG layer of a semiconductor device according to the second embodiment of the present invention.

FIG. 9A is a scanning electron microscope (SEM) image illustrating the surface of a semiconductor device according to the second embodiment of the present invention.

FIG. 9B is an SEM image illustrating the surface of a conventional semiconductor device having an SEG layer formed after a wet cleaning only.

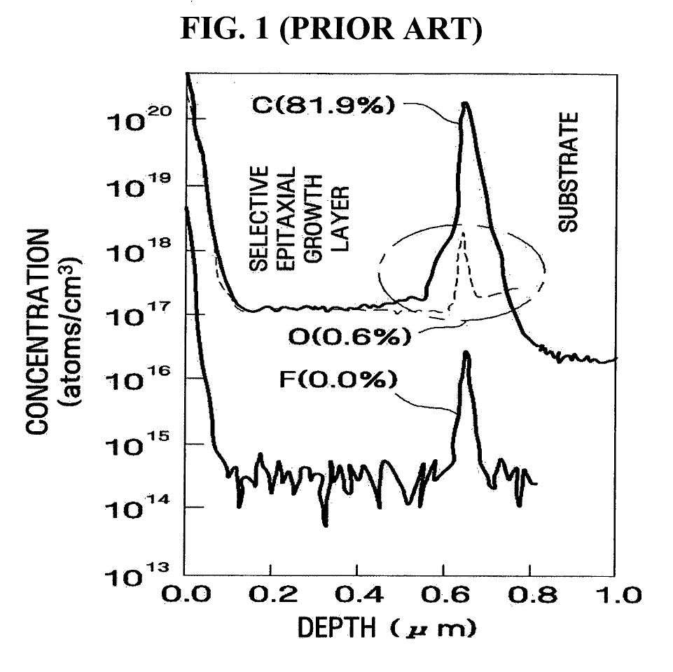

### DETAILED DESCRIPTION OF PREFERRED EMBODIMENTS OF THE INVENTION

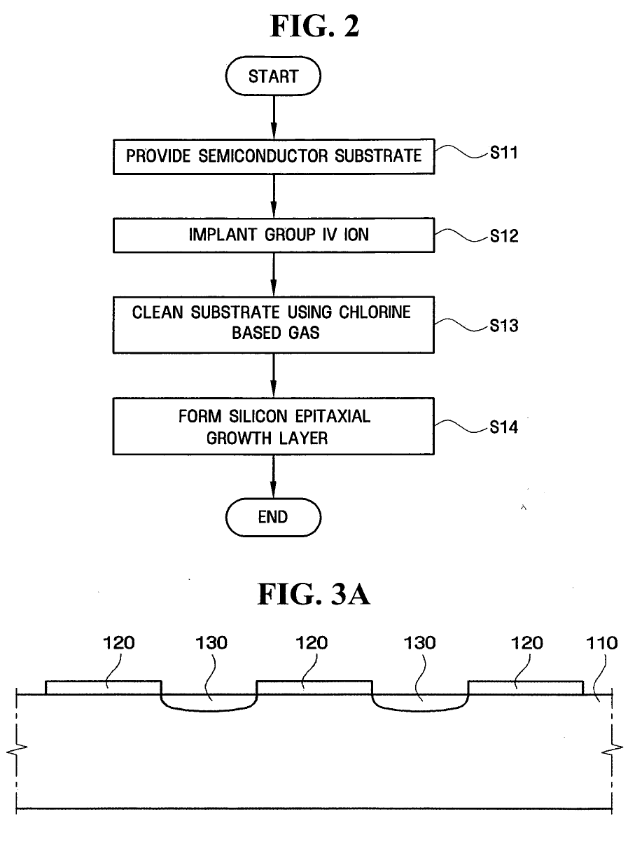

A method of manufacturing a semiconductor device according to the present invention will now be described more fully with reference to FIGS. 2 through 9, in which preferred embodiments of this invention are shown.

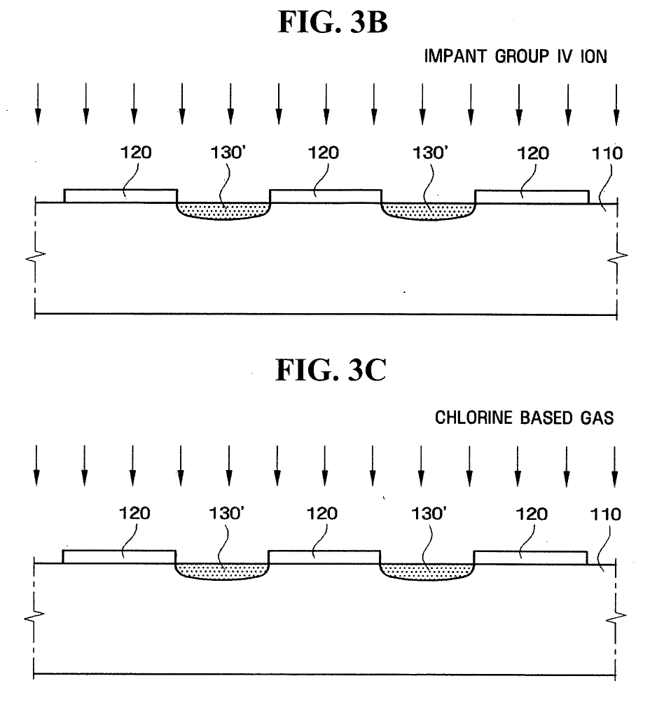

FIG. 2 is a flowchart of a method of manufacturing a semiconductor device according to a first embodiment of the present invention, and FIGS. 3A through 3D are sectional views of a semiconductor device in manufacturing stages according to the first embodiment of the present invention.

Referring to FIG. 2, a semiconductor substrate, which is doped to a predetermined concentration, is provided, in operation S11.

Referring to FIG. 3A, a semiconductor substrate is prepared. The semiconductor substrate 110 can be formed by any substrate on which a silicon epitaxial growth is possible, such as a silicon substrate.

A material layer pattern 120, for example, an oxide layer or a nitride layer pattern, is formed on the semiconductor substrate 110 and dopant areas 130 are formed by diffusion or ion implantation on portions where the material layer pattern 120 is not formed.

In this case, examples of the dopant include boron (B), phosphorus (P), arsenic (As), carbon (C), gallium (G), and antimony (Sb), preferably B. When the dopant areas 130 are highly doped, the concentration ranges from 10¹⁹ to 10²¹ atom/cm³.

Thereafter, a group IV ion is implanted to the substrate 110, in operation S12.

Referring to FIG. 3B, the group IV ion is implanted to the substrate 110 in order to change the dopant areas 130 formed on the semiconductor substrate 110 into amorphous areas 130′. In this case, the group IV ion is implanted to a depth for changing the dopant areas 130 into the amorphous areas 130′.

Examples of the group IV ion include C, silicon (Si), and germanium (Ge), preferably Ge. The concentration of the group IV ion may be 10¹⁴ to 10¹⁶ atom/cm³.

When the amorphous areas 130′ are formed by implanting the group IV ion to the dopant areas 130 on the substrate 110, a crystallization occurs easily when forming a silicon epitaxial growth (SEG) layer in order to form an excellent, high-quality SEG layer.

Thereafter, the substrate 110 is cleaned using a chlorine-based gas, in operation S13.

Referring to FIG. 3C, the surface of the semiconductor substrate 110 having the amorphous areas 130′ is cleaned using a chlorine-based gas. Examples of the chlorine-based gas include HCl, Cl₂, BCl₃, and CCl₄, preferably HCl.

The temperature of the cleaning for removing contaminants from the semiconductor substrate 110 can be lowered from over 1,000° C. to less than 850° C. by using the chlorine-based gas. The cleaning using the chlorine-based gas may be performed at a temperature of 500 to 750° C.

When HCl gas is used for the chlorine gas of the cleaning, the flow rate of the HCl gas to a carrier gas (H₂) is 1 to 100, the flow speed of the HCl gas is 1 to 100 slm, the flow speed of H₂ is 0.1 to 10 slm, the temperature is 500 to 750° C., and the cleaning is performed for 1 to 100 seconds under a pressure of 0.1 to 800 Torr.

Thereafter, an SEG layer is formed on the substrate 110, in operation S14.

Referring to FIG. 3D, the SEG layer 140 is formed on the amorphous areas 130′ of the semiconductor substrate 110. In this case, the SEG layer 140 can be formed in-situ with the cleaning.

Since the cleaning and the SEG layer forming are performed in different chambers in a conventional method, the semiconductor substrate may be re-contaminated by being exposed to the air while moving the substrate to a chamber for forming the SEG layer. However, the cleaning and the SEG layer forming are formed in-situ in the method according to the present invention; thus the re-contamination of the substrate can be prevented.

When the epitaxial growing conditions are controlled while forming the SEG layer 140 on the amorphous areas 130′ of the semiconductor substrate 110, the growing rate of the epitaxial layer on the semiconductor substrate 110 can be increased compared to the growing rate of the epitaxial layer on the material layer pattern 120. As a result, the SEG layer 140 can be formed only on the amorphous areas 130′.

In this case, the SEG layer 140 may be formed by chemical vapor deposition (CVD), reduced pressure chemical vapor deposition (RPCVD), or ultra high vacuum chemical vapor deposition (UHVCCD); however, the method of forming the SEG layer 140 can vary.

The SEG layer 140 can be formed by the CVD using the mixture of silicon source gas and carrier gas at a temperature of 700 to 750° C. under a pressure of 5 to 200 Torr.

Examples of the silicon source gas include SiH₄ gas, SiCl₄ gas, SiH₂Cl₂ gas, and SiHCl₃ gas. In addition, the examples of the carrier gas include H₂ gas, N₂ gas, and Ar gas. Preferably, the silicon source gas and the carrier gas may be SiH₄ gas and the H₂ gas, respectively.

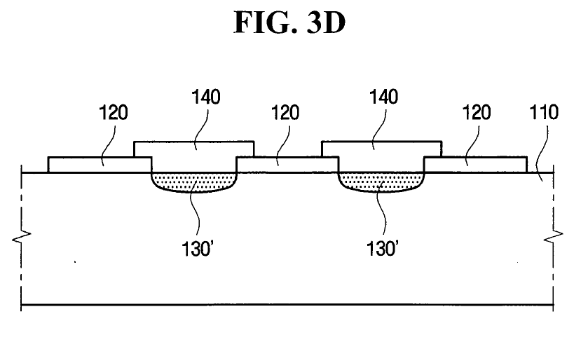

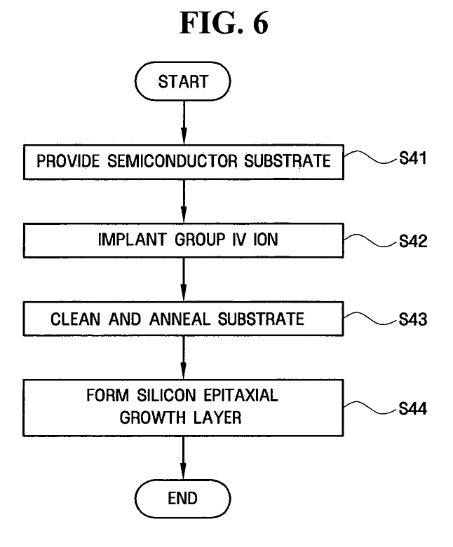

FIGS. 4 through 6 are flowcharts of a method of manufacturing a semiconductor device according to second through fourth embodiments of the present invention, respectively, and FIG. 7 is a graph illustrating process conditions for cleaning, annealing, and SEG layer forming included in the method of manufacturing a semiconductor device according to the second through fourth embodiments of the present invention.

Referring to FIG. 4, a method of manufacturing a semiconductor device according to the second embodiment of the present invention includes providing a semiconductor substrate having dopant areas with a predetermined concentration, in operation S21, implanting group IV ions to the substrate, in operation S22, annealing the substrate, in operation S23, cleaning the substrate using a chlorine-based gas, in operation S24, and forming an SEG layer, in operation S25.

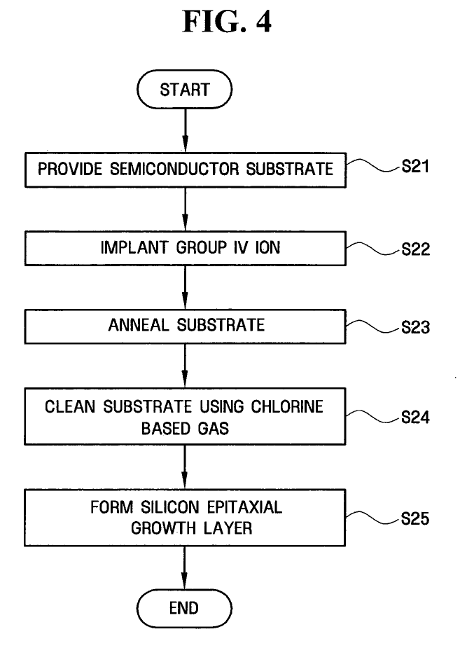

Referring to FIG. 5, a method of manufacturing a semiconductor device according to the third embodiment of the present invention includes providing a semiconductor substrate having dopant areas with a predetermined concentration, in operation S31, implanting group IV ions to the substrate, in operation S32, cleaning the substrate using a chlorine-based gas, in operation S33, annealing the substrate, in operation S34, and forming an SEG layer, in operation S35.

The methods of manufacturing the semiconductor device according to the second and third embodiments of the present invention are the same as the method of manufacturing the semiconductor device according to the first embodiment of the present invention except the annealing of the substrate before or after the cleaning of the substrate.

The annealing included in the methods of manufacturing the semiconductor device according to the second and third embodiments of the present invention is performed to recover and return the physical transformation of the substrate caused by the ion implantation. The annealing can be performed at a temperature of 650 to 850° C. under a H₂ atmosphere. In order to properly recover the transformation of the substrate, the temperature of the annealing should be the same as or higher than the temperature of the cleaning.

By performing the annealing, the crystalline property of the amorphous areas can be recovered before forming the SEG layer; thus the SEG layer with a higher crystalline property can be formed.

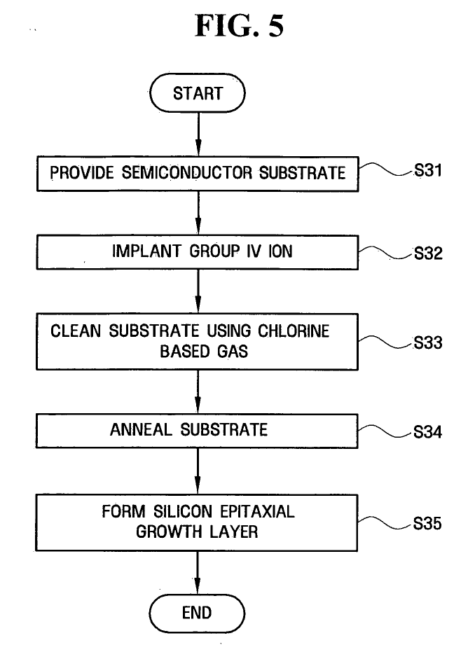

FIG. 6 is a flowchart illustrating a method of manufacturing a semiconductor device according to the fourth embodiment of the present invention.

Referring to FIG. 6, the method of manufacturing a semiconductor device according to the fourth embodiment of the present invention includes providing a semiconductor substrate having dopant areas with a predetermined concentration, in operation S41, implanting group IV ions to the substrate, in operation S42, annealing the substrate while cleaning the substrate using a chlorine-based gas, in operation S43, and forming an SEG layer, in operation S44.

The method of manufacturing the semiconductor device according to the fourth embodiment of the present invention is the same as the method of manufacturing the semiconductor device according to the first embodiment of the present invention except the cleaning of the substrate while annealing the substrate. Referring to FIG. 7, the cleaning can be performed while performing the annealing.

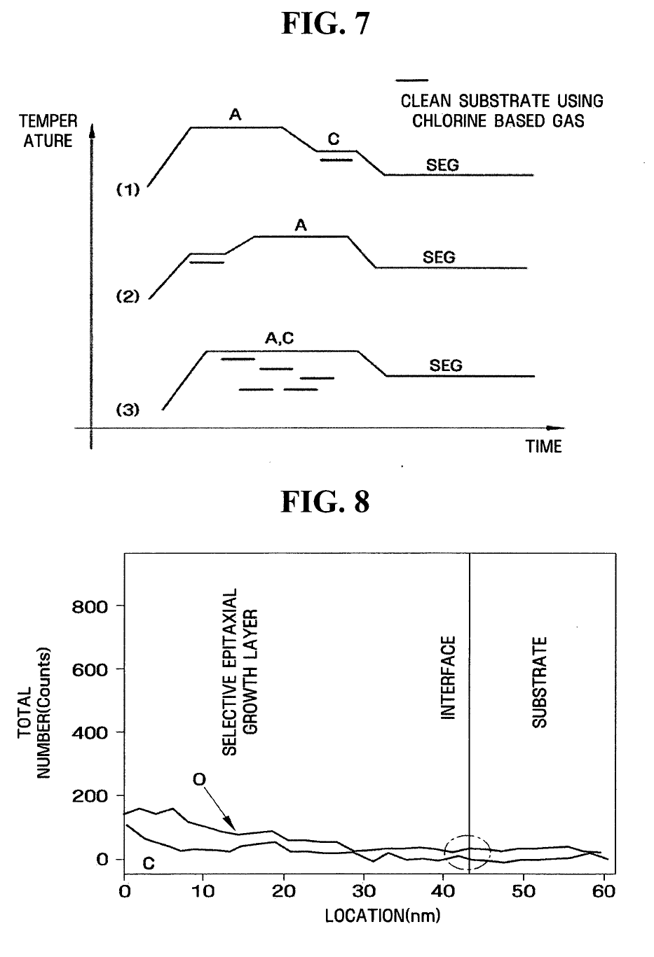

FIG. 8 is a graph illustrating the removal rate of a contaminant from the interface between the substrate and the SEG layer of the semiconductor device according to the second embodiment of the present invention. In this case, the removal rate of the contaminant was measured by using an energy dispersive X-ray spectroscopy (EDX) device.

Referring to FIG. 8, when the substrate is cleaned at a temperature of 700° C. using a chlorine-based gas, in particular HCl gas, before forming the SEG layer and the SEG layer is formed in-situ, the contaminant, such as C, can be completely removed from the interface between the substrate and the SEG layer.

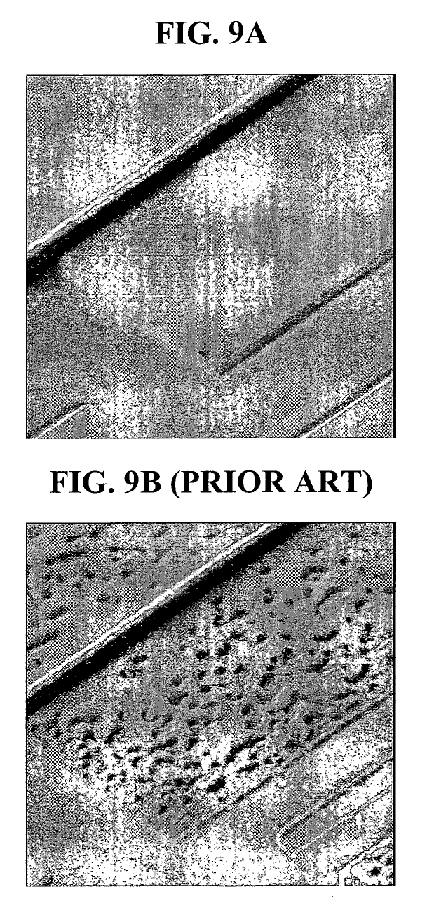

FIG. 9A is a scanning electron microscope (SEM) image illustrating the surface of the semiconductor device according to the second embodiment of the present invention and FIG. 9B is an SEM image illustrating the surface of a conventional semiconductor device having an SEG layer formed after a wet cleaning only.

Referring to FIGS. 9A and 9B, the quality of the surface of the conventional semiconductor device having the SEG layer formed after the wet cleaning only is low.

On the other hand, when the amorphous areas are formed by implanting the group IV ion, such as Ge, the crystalline property of the amorphous areas is recovered by annealing, the substrate is cleaned at a temperature of 700° C. using the chlorine-based gas, such as HCl gas, and the SEG layer is formed in-situ, the quality of the SEG layer is improved.

A method of manufacturing a semiconductor device according to the present invention provides at least the following advantages.

First, a contaminant may be removed from the surface of the substrate using a chlorine-based gas at a low temperature, and an excellent SEG layer may be obtained by implanting group IV ion to the substrate.

Second, since the cleaning and the forming of the SEG layer are performed in-situ, the substrate is prevented from being re-contaminated after the cleaning; thus the excellent SEG layer may be obtained.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. A method of manufacturing a semiconductor device, the method comprising:
providing a semiconductor substrate including dopant areas with a predetermined concentration;
implanting group IV ions into the substrate;
cleaning the substrate using a chlorine-based gas; and
forming a silicon epitaxial growth (SEG) layer on the substrate.

2. The method of claim 1, wherein the cleaning and the forming of the SEG layer are performed in-situ.

3. The method of claim 1, wherein the chlorine-based gas is HCl gas.

4. The method of claim 1, wherein the cleaning of the substrate is performed at a temperature lower than 850° C.

5. The method of claim 1, wherein in the implanting of the group IV ions, the group IV ions are implanted to a depth sufficient to change the dopant areas of the semiconductor substrate into amorphous areas.

6. The method of claim 5, wherein in the implanting of the group IV ions, the concentration of the group IV ions is in the range of 10¹⁴ to 10¹⁶ atom/cm³.

7. The method of claim 1, wherein the group IV ions comprise at least one of carbon (C), silicon (Si), and germanium (Ge) ions.

8. The method of claim 1, wherein the group IV ions are germanium (Ge) ions.

9. The method of claim 1, wherein in the providing of the semiconductor substrate, the dopant comprises at least one of boron (B), phosphorus (P), arsenic (As), and carbon (C).

10. The method of claim 1, wherein in the providing of the semiconductor substrate, the dopant comprises boron (B).

11. The method of claim 1, further comprising annealing the semiconductor substrate before and/or after the cleaning of the substrate.

12. The method of claim 11, wherein the cleaning of the substrate is performed at a temperature lower than the temperature of the annealing.

13. The method of claim 12, wherein the annealing is performed at a temperature in the range of 650 to 850° C.

14. The method of claim 1, wherein annealing is performed at the same time as the cleaning.

15. The method of claim 11, wherein the annealing is performed under an H2 atmosphere.

16. A method of manufacturing a semiconductor device, the method comprising:
providing a semiconductor substrate having dopant areas with a predetermined concentration;
implanting germanium ions into the substrate and changing the substrate into an amorphous substrate;
cleaning the substrate at a temperature lower than 850° C. using HCl gas; and
forming an SEG layer on the substrate in-situ.

17. The method of claim 16, wherein in the implanting of the germanium ions, the germanium ions are implanted to a depth sufficient to change the dopant areas of the semiconductor substrate into amorphous areas.

18. The method of claim 17, wherein in the implanting of the germanium ions, the concentration of the germanium ions is in the range of 10¹⁴ to 10¹⁶ atom/cm³.

19. The method of claim 16, wherein in the providing of the semiconductor substrate, the dopant is boron (B).

20. The method of claim 16, further comprising annealing the semiconductor substrate before and/or after the cleaning of the substrate.

21. The method of claim 20, wherein the cleaning of the substrate is performed at a temperature lower than the temperature of the annealing.

22. The method of claim 21, wherein the annealing is performed at a temperature in the range of 650 to 850° C.

23. The method of claim 16, wherein annealing is performed at the same time as the cleaning.

24. The method of claim 20, wherein the annealing is performed under an H₂ atmosphere.
